(19) United States
(12) Patent Application Publication
(10) Pub. No.: US 2015/0206812 A1
(43) Pub. Date: Jul. 23, 2015

(54) SUBSTRATE AND METHOD OF FORMING THE SAME

(71) Applicant: QUALCOMM Incorporated, San Diego, CA (US)

(72) Inventors: Chin-Kwan KIM, San Diego, CA (US); Milind Pravin SHAH, San Diego, CA (US); Manuel ALDRETE, San Diego, CA (US)

(73) Assignee: QUALCOMM Incorporated, San Diego, CA (US)

(21) Appl. No.: 14/263,823

(22) Filed: Apr. 28, 2014

Related U.S. Application Data
(60) Provisional application No. 61/930,745, filed on Jan. 23, 2014.

(51) Int. Cl. H01L 23/053; H01L 21/3213; H01L 21/306; H01L 21/3205

(52) U.S. Cl. CPC H01L 23/053; H01L 21/32051; H01L 21/32133; H01L 21/32139; H01L 21/30604

(57) ABSTRACT

Methods and apparatus for cavity formation in a semiconductor package substrate are provided. In one embodiment, a method for producing at least one cavity within a semiconductor package substrate includes etching the semiconductor package substrate from a surface of the semiconductor package substrate at least one intended cavity location in order to obtain at least one cavity. The method includes depositing a copper portion on a substrate in a cavity location. Next, the method includes masking the substrate while keeping the copper portion exposed. Lastly, the method includes etching the substrate to form a cavity by etching away the copper portion. The structure formed includes a cavity that extends partially through the substrate without damaging a glass fabric embedded in the substrate.

### CROSS-REFERENCE TO RELATED APPLICATION

The present Application for Patent claims the benefit of U.S. Provisional Application No. 61/930,745, entitled “SUBSTRATE AND METHOD OF FORMING THE SAME,” filed Jan. 23, 2014, assigned to the assignee hereof, and expressly incorporated herein by reference in its entirety.

### FIELD OF DISCLOSURE

This disclosure relates generally to semiconductors, and more specifically, but not exclusively, to methods for cavity formation in semiconductor package substrates.

### BACKGROUND

Conventionally, semiconductor packaging is formed by using a various methods to form a layered substrate followed by a mechanical process such as routing or laser ablation to form a cavity in the substrate. However, the mechanical processes are not cost effective, result in a low production volume, and leave an uneven surface.

Accordingly, there are long-felt industry needs for methods that improve upon conventional methods including the improved methods and apparatus provided hereby.

The inventive features that are characteristic of the teachings, together with further objects and advantages, are better understood from the detailed description and the accompanying figures. Each of the figures is provided for the purpose of illustration and description only, and does not limit the present teachings.

### SUMMARY

The following presents a simplified summary relating to one or more aspects and/or embodiments associated with the apparatus and methods disclosed herein. As such, the following summary should not be considered an extensive overview relating to all contemplated aspects and/or embodiments, nor should the following summary be regarded to identify key or critical elements relating to all contemplated aspects and/or embodiments or to delineate the scope associated with any particular aspect and/or embodiment. Accordingly, the following summary has the sole purpose to present certain concepts relating to one or more aspects and/or embodiments relating to the apparatus and methods disclosed herein in a simplified form to precede the detailed description presented below.

Some exemplary embodiments of the disclosure are directed to systems, apparatus, and methods for cavity formation in a semiconductor package.

In some embodiments of the disclosure, the system, apparatus, and method includes forming a plating portion on a cavity location of a carrier, laminating the carrier with a composite layer, separating the carrier from the composite layer, forming a substrate with the separated composite layer and the plating portion, and forming a cavity in the substrate by etching an exposed plating portion where the cavity extends partially through the substrate.

Other objects and advantages associated with the apparatus and methods disclosed herein will be apparent to those skilled in the art based on the accompanying drawings and detailed description.

### BRIEF DESCRIPTION OF THE DRAWINGS

The accompanying drawings are presented to describe examples of the present teachings, and are not limiting. The accompanying drawings are presented to aid in the description of embodiments of the disclosure and are provided solely for illustration of the embodiments and not limitation thereof.

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure, and in which:

FIG. 1 depicts a conventional prior art cavity formation process.

FIG. 2 depicts an exemplary method and apparatus in accordance with an embodiment of the disclosure.

FIG. 3 depicts another exemplary method and apparatus in accordance with an embodiment of the disclosure that shows a cross-section of a package on package semiconductor package.

FIG. 4 depicts an exemplary method and apparatus in accordance with an embodiment of the disclosure that shows a cross section with stacked substrates.

FIG. 5 depicts an exemplary method and apparatus in accordance with an embodiment of the disclosure that shows an embedded pattern included in the substrate.

FIG. 6 depicts an exemplary method and apparatus in accordance with an embodiment of the disclosure that shows a cross section of a multilayer substrate with a cavity.

FIG. 7A depicts an exemplary method and apparatus in accordance with an embodiment of the disclosure that shows the formation of a copper plated substrate prior to cavity formation.

FIG. 7B depicts an exemplary method and apparatus in accordance with an embodiment of the disclosure that shows formation of a cavity in a substrate.

FIG. 8 depicts additional exemplary methods and apparatus in accordance with an embodiment of the disclosure that shows an underfill and an adhesive.

FIG. 9A depicts an exemplary method and apparatus in accordance with an embodiment of the disclosure that shows the formation of a copper plated substrate prior to cavity formation.

FIG. 9B depicts an exemplary method and apparatus in accordance with an embodiment of the disclosure that shows formation of a cavity in a substrate.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Methods for cavity formation in a semiconductor package substrate are provided. The exemplary methods disclosed herein advantageously address the long-felt industry needs, as well as other previously unidentified needs, and mitigate shortcomings of the conventional methods. For example, an advantage provided by the disclosed methods herein is an improvement in cost savings, production volume, reduced top ball pad pitch, and surface smoothness over conventional devices.

Various aspects are disclosed in the following description and related drawings to show specific examples relating to exemplary embodiments of the disclosure. Alternate embodiments will be apparent to those skilled in the pertinent art upon reading this disclosure, and may be constructed and practiced without departing from the scope or spirit of the disclosure. Additionally, well-known elements will not be described in detail or may be omitted so as to not obscure the relevant details of the aspects and embodiments disclosed herein.

The word “exemplary” is used herein to mean “serving as an example, instance, or illustration.” Any embodiment described herein as “exemplary” is not necessarily to be construed as preferred or advantageous over other embodiments. Likewise, the term “embodiments” does not require that all embodiments include the discussed feature, advantage or mode of operation. Use of the terms “in one example,” “an example,” “in one feature,” and/or “a feature” in this specification does not necessarily refer to the same feature and/or example. Furthermore, a particular feature and/or structure can be combined with one or more other features and/or structures. Moreover, at least a portion of the apparatus described hereby can be configured to perform at least a portion of a method described hereby.

The terminology used herein is for the purpose of describing particular embodiments only and is not intended to be limiting of embodiments of the invention. As used herein, the singular forms “a,” “an,” and “the” are intended to include the plural forms as well, unless the context clearly indicates otherwise. It will be further understood that the terms “comprises”, “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element. Coupling and/or connection between the elements can be physical, logical, or a combination thereof. As employed herein, elements can be “connected” or “coupled” together, for example, by using one or more wires, cables, and/or printed electrical connections, as well as by using electromagnetic energy. The electromagnetic energy can have wavelengths in the radio frequency region, the microwave region and/or the optical (both visible and invisible) region. These are several non-limiting and non-exhaustive examples.

It should be understood that the term “signal” can include any signal such as a data signal, audio signal, video signal, multimedia signal, analog signal, and/or digital signal. Information and signals can be represented using any of a variety of different technologies and techniques. For example, data, an instruction, a process step, a command, information, a signal, a bit, and/or a symbol described in this description can be represented by a voltage, a current, an electromagnetic wave, a magnetic field and/or particle, an optical field and/or particle, and any combination thereof.

Any reference herein to an element using a designation such as “first,” “second,” and so forth does not limit the quantity and/or order of those elements. Rather, these designations are used as a convenient method of distinguishing between two or more elements and/or instances of an element. Thus, a reference to first and second elements does not mean that only two elements can be employed, or that the first element must necessarily precede the second element. Also, unless stated otherwise, a set of elements can comprise one or more elements. In addition, terminology of the form “at least one of: A, B, or C” used in the description or the claims can be interpreted as “A or B or C or any combination of these elements.”

Further, many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of the invention may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

In this description, certain terminology is used to describe certain features. The term “mobile device” can describe, and is not limited to, a mobile phone, a mobile communication device, a pager, a personal digital assistant, a personal information manager, a mobile hand-held computer, a laptop computer, a wireless device, a wireless modem, and/or other types of portable electronic devices typically carried by a person and/or having communication capabilities (e.g., wireless, cellular, infrared, short-range radio, etc.). Further, the terms “user equipment” (UE), “mobile terminal,” “mobile device,” and “wireless device,” can be interchangeable.

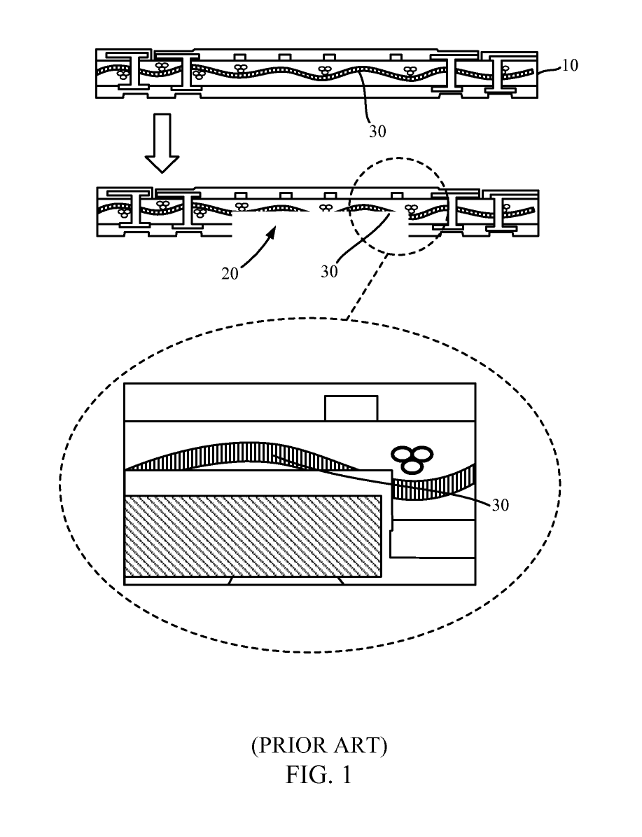

FIG. 1 depicts a conventional process for mechanical cavity formation. In FIG. 1, a layered substrate 10 is formed using conventional SR coating, exposing, and developing techniques. After the substrate 10 is formed, a cavity 20 is created in the substrate 10. The cavity 20 is formed using conventional mechanical techniques such as routing or laser ablation. As can be seen in FIG. 1, a glass fabric 30 embedded in substrate 10 is damaged during cavity 20 formation. During formation of the substrate 10, the glass fabric 30 is embedded in the center of substrate 10 vertically and in a continuous manner from a first side to a second side horizontally. In the next stage, the cavity 20 is formed in the substrate 10 by removal of the substrate material including portions of the embedded fabric 30 in the region of cavity 20. As can be seen, the embedded fabric is damaged when portions of substrate material are removed to form the cavity 20 and the fabric 30 is no longer continuous horizontally from the first side to the second side.

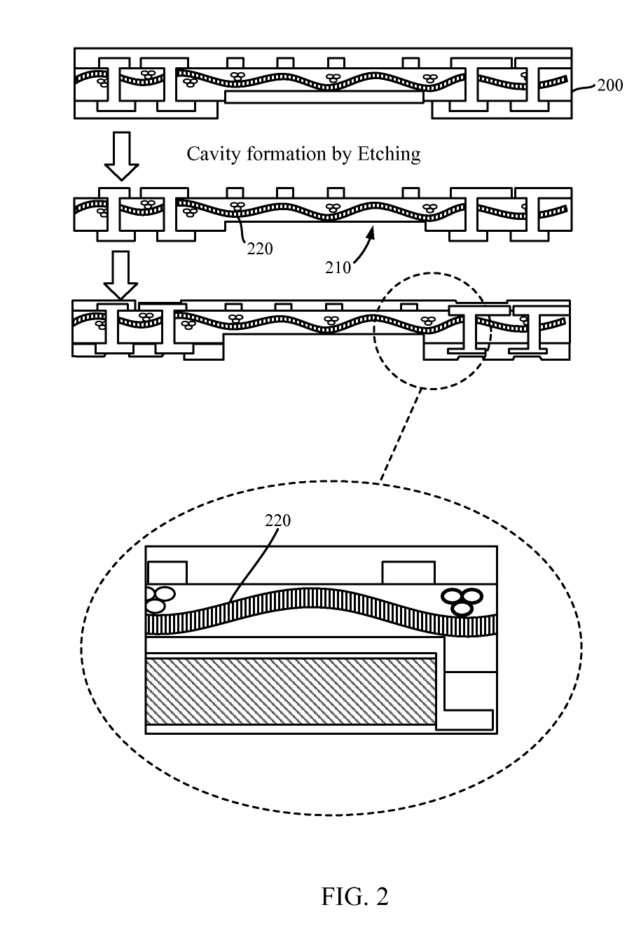

FIG. 2 depicts an exemplary embodiment of an apparatus and method for cavity formation without damaging layers of a substrate. In FIG. 2, substrate 200 is formed without a cavity. During formation of the substrate 200, the glass fabric 220 may be embedded in the substrate 200. The glass fabric may be offset from a vertical center of the substrate 200 and in a continuous manner from a first side to a second side horizontally. In the next stage, the cavity 210 may be formed in the substrate 200 by removal of the substrate material using an etching technique. As can be seen in FIG. 2, the embedded fabric 220 is not damaged when portions of substrate material are removed to form the cavity 210 and the fabric 220 remains continuous horizontally from the first side to the second side.

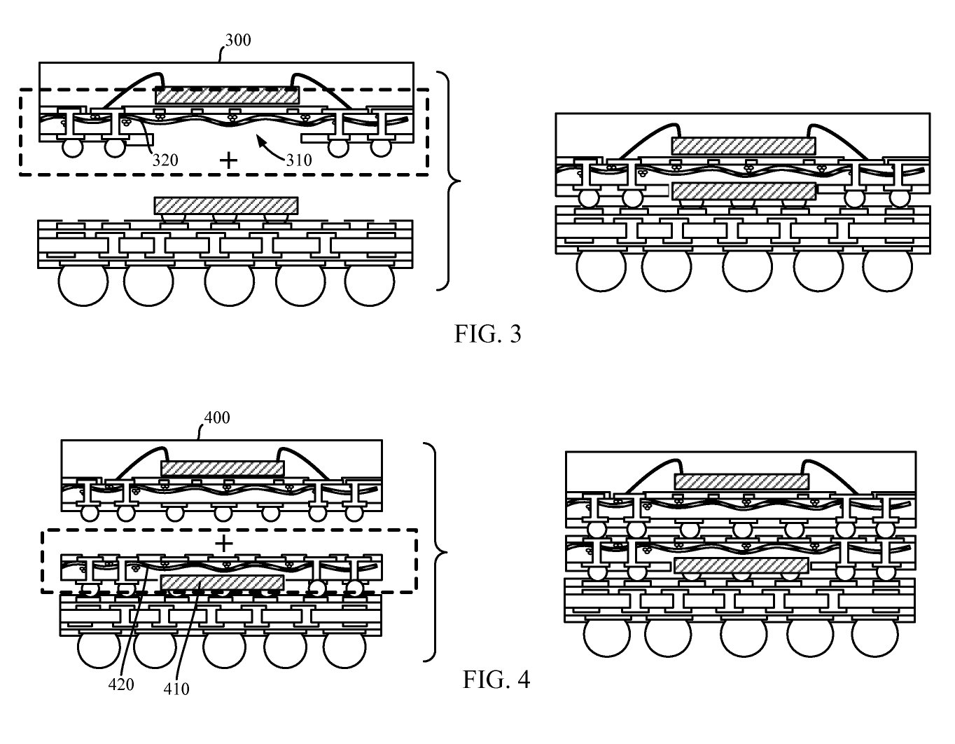

FIG. 3 depicts an exemplary embodiment of an apparatus and method for cavity formation without damaging layers of a substrate. In FIG. 3, substrate 300 is formed without a cavity. Using etching techniques, cavity 310 is formed in substrate 300. As can be seen in FIG. 3, glass fabric 320, embedded in substrate 300, is not damaged by etching cavity 310 in substrate 300.

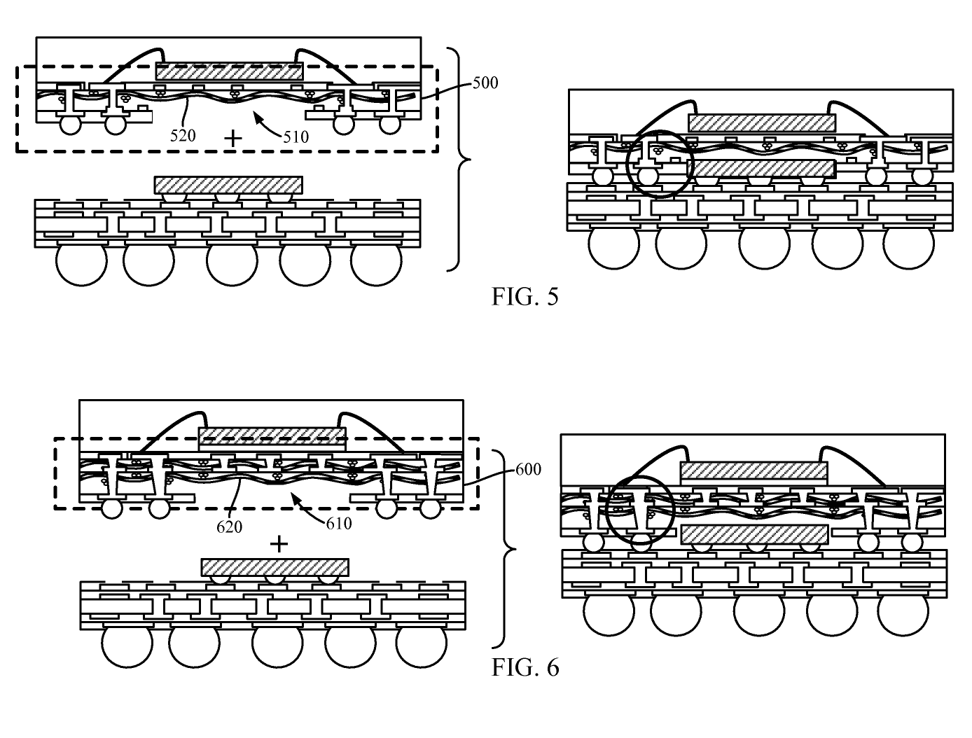

FIG. 4 depicts an exemplary embodiment of an apparatus and method for cavity formation without damaging layers of a substrate. In FIG. 4, substrate 400 is formed without a cavity. Using etching techniques, cavity 410 is formed in substrate 400. As can be seen in FIG. 4, glass fabric 420, embedded in substrate 400, is not damaged by etching cavity 410 in substrate 400.

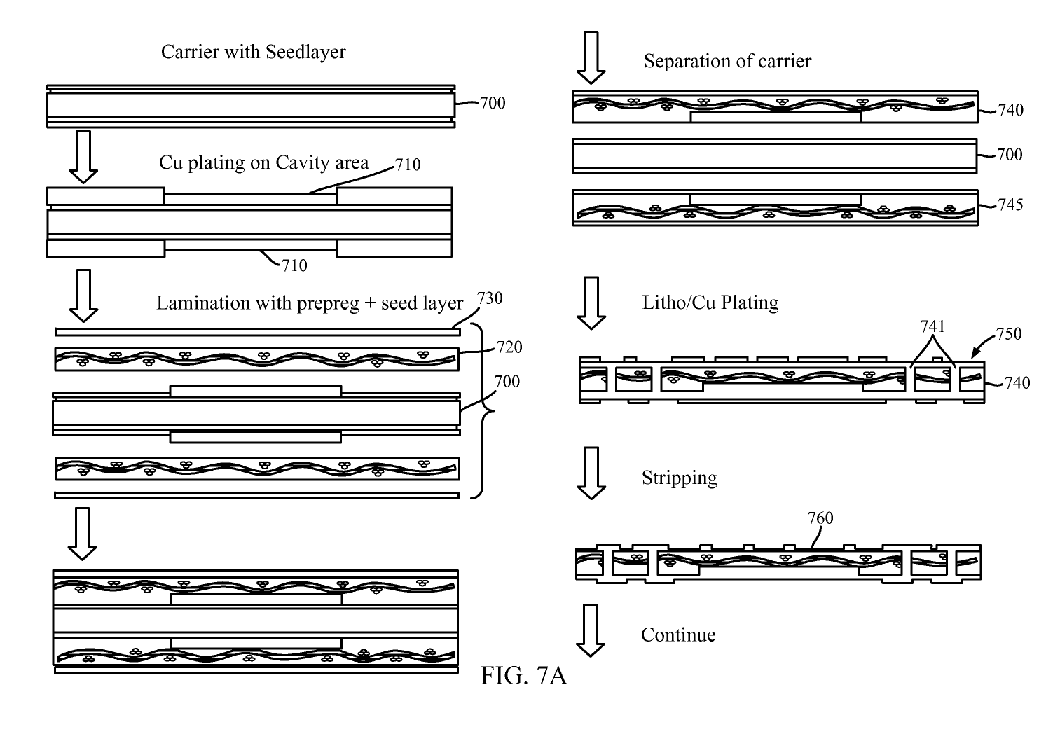

FIG. 5 depicts an exemplary embodiment of an apparatus and method for cavity formation without damaging layers of a substrate. In FIG. 5, substrate 500 is formed without a cavity. Using etching techniques, cavity 510 is formed in substrate 500. As can be seen in FIG. 5, glass fabric 520, embedded in substrate 400, is not damaged by etching cavity 510 in substrate 500.

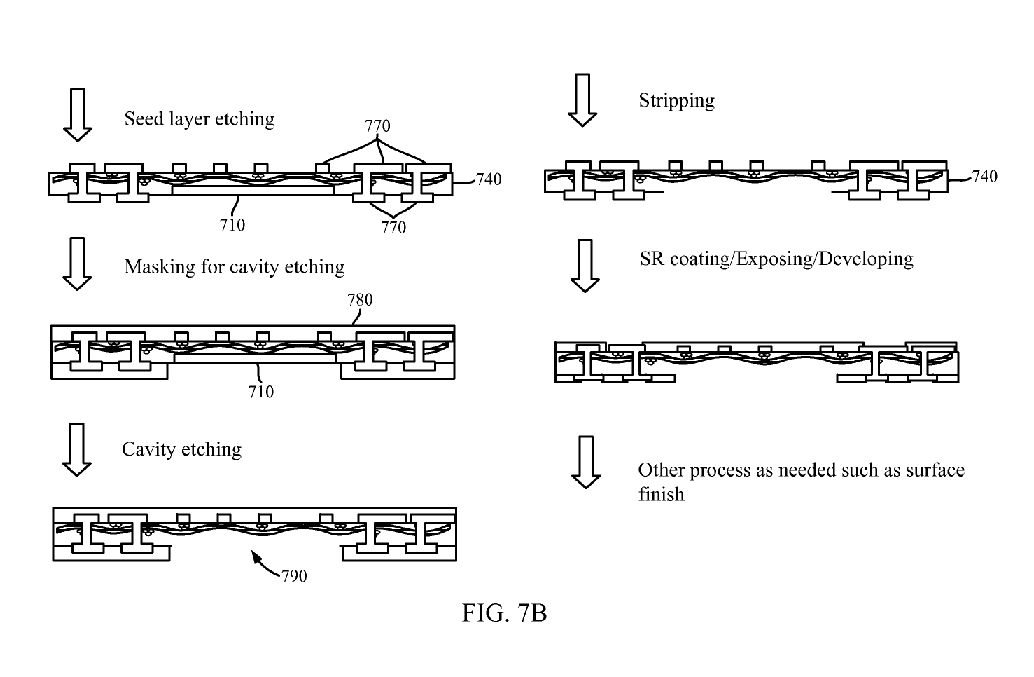

FIG. 6 depicts an exemplary embodiment of an apparatus and method for cavity formation without damaging layers of a substrate. In FIG. 6, substrate 600 is formed without a cavity. Using etching techniques, cavity 610 is formed in substrate 600. As can be seen in FIG. 6, glass fabric 620, embedded in substrate 600, is not damaged by etching cavity 610 in substrate 600.

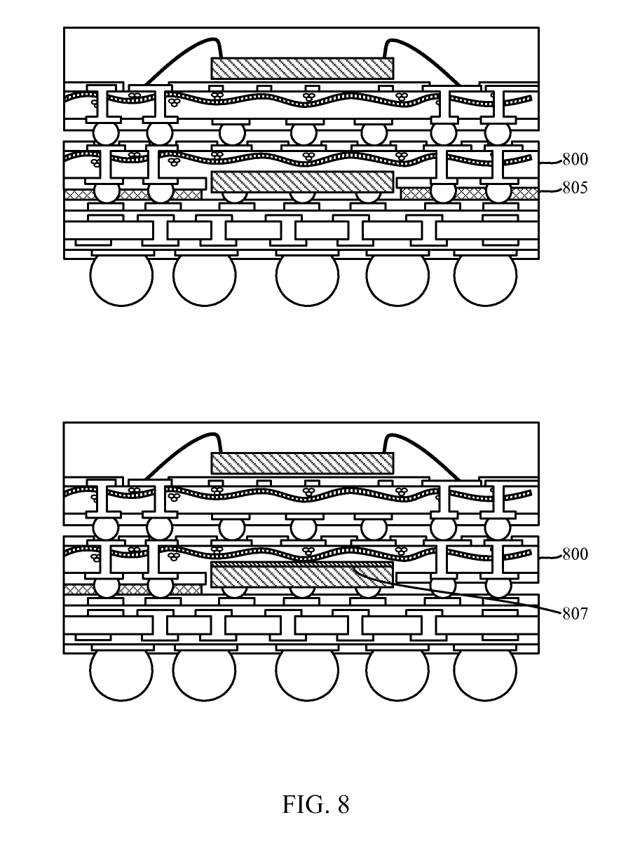

FIGS. 7A and 7B depict an exemplary embodiment of an apparatus and method for cavity formation without damaging layers of a substrate. In FIG. 7A, a carrier with seed layer 700 is formed. Next, copper plating 710 is formed on carrier 700. The copper plating 710 is formed in the area or location of the future cavity. Next, the copper plated carrier 700 is laminated with a prepreg layer 720 and another seed layer 730. Prepreg 720 can be an impregnated resin layer with embedded glass fabric or similar type of layer. The embedded glass fabric may be embedded such that the glass fabric is offset from the center line of the prepreg layer 720. Alternatively, the prepreg layer can be constructed such that the embedded glass fabric is offset from the center line of the composite prepreg layer even though it may not be offset from the layer it is originally embedded within. The embedded glass fabric can be continuous or nearly continuous throughout the prepreg layer 720. In alternative constructions, the glass fabric can be centered and the cavity can be formed without damaging the centered glass fabric. Carrier 700, prepreg 720 and seed layer 730 are laminated together to form one composite structure as shown. Although top and bottom layers are shown in FIG. 7A for the composite structure, the composite structure can be formed on one side only if so desired.

The carrier 700 is then separated from the composite structure forming separate substrates 740 and 745. We will describe further processing of the substrate with respect to only one substrate, but it should be understood that the further process can be applied to both substrates. After separating the carrier 700 from substrate 740, vias 741 are formed in substrate 740 and substrate 740 is coated with a combination litho/cu plating layer 750. The plating layer 750 can be composed of lithographic resin and copper plating. The plating layer 750 is then stripped to expose various portions of substrate 740. The portions exposed can be arranged as needed to achieve a desired pattern.

The process is continued as shown in FIG. 7B according to an exemplary embodiment. In FIG. 7B, substrate 740 with exposed copper layer is further etched to remove seed layer 760 but keep copper portions 770 and copper plating 710. Following this etching process, a mask layer 780 is formed on substrate 740 except in the location of the future cavity or copper plating 710. Another etching process is applied to substrate 740 to form a cavity 790. In this etching process, the masked portions of substrate 740 are protected from etching and only the exposed copper plating 710 is etched away. After forming cavity 790, the masking layer 780 is stripped away from substrate 740. Next, a three stage process is applied to substrate 740. In the three stage process: a SR coating is applied, exposed, and then developed. After this three stage process, the substrate 740 structure may be ready for further processing such as surface finishing.

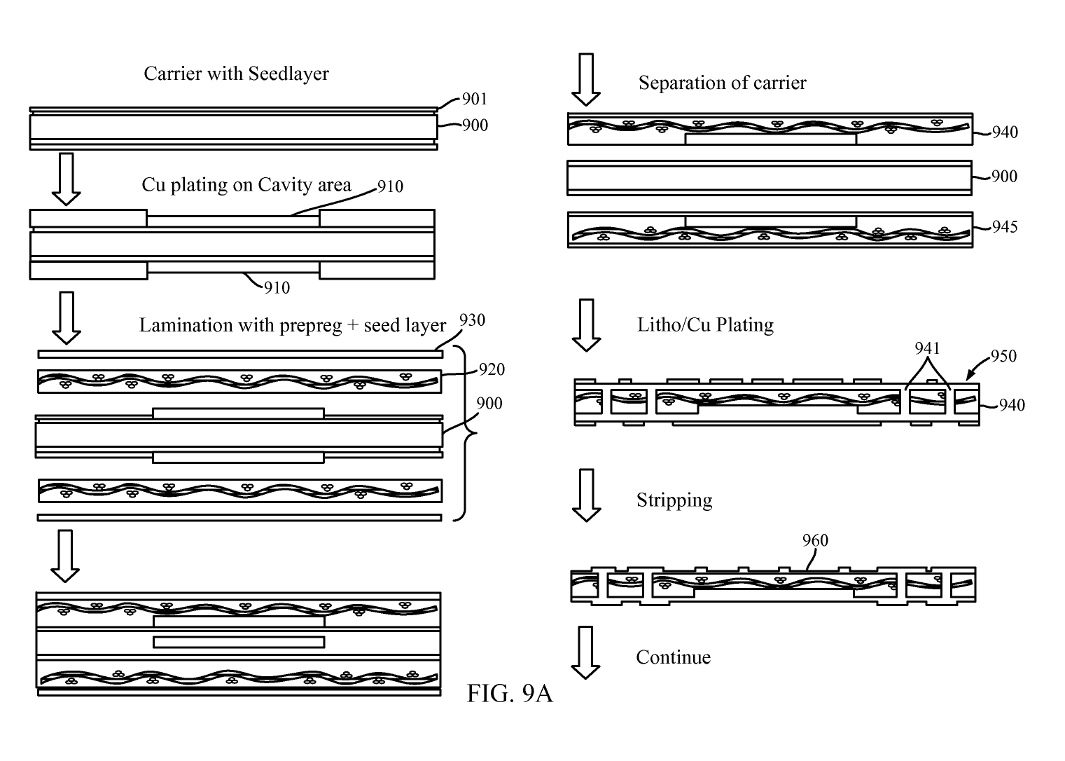

FIG. 8 depicts an exemplary embodiment of an apparatus and method for cavity formation without damaging layers of a substrate. In FIG. 8, substrate 800 is formed without a cavity. In one embodiment, substrate 800 includes an underfill 805 between the gap to protect solder interconnection. In another embodiment, substrate 800 includes an adhesive 807 between an interposer and a die to provide mechanical strength.

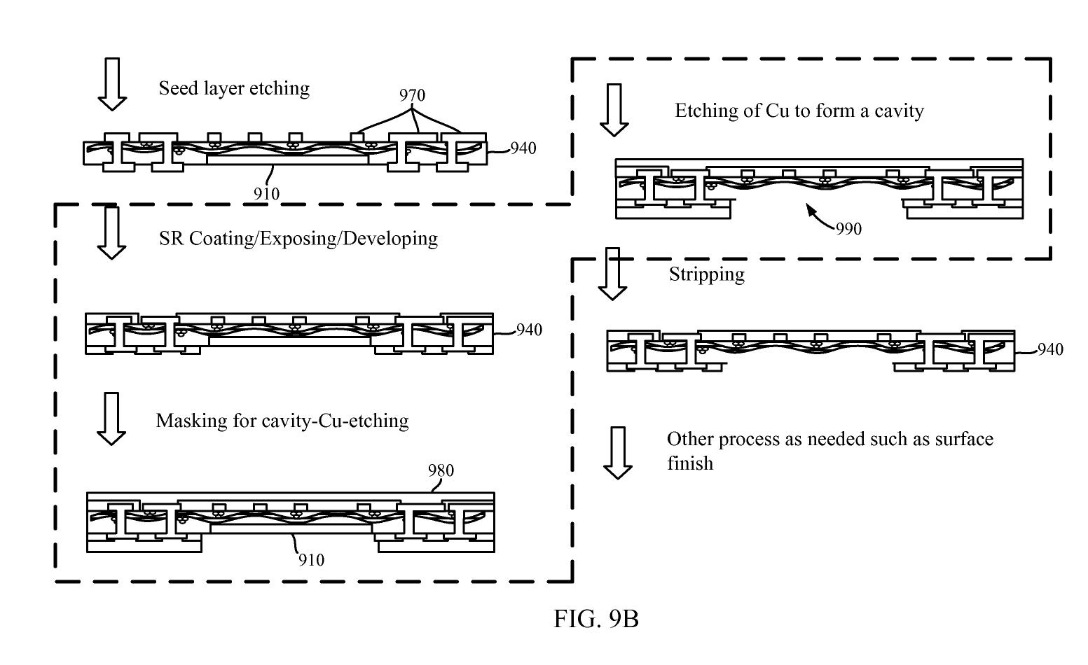

FIGS. 9A and 9B depict an exemplary embodiment of an apparatus and method for cavity formation without damaging layers of a substrate. In FIG. 9A, a carrier 900 with seed layer 901 is formed. Next, copper plating 910 is formed on carrier 900. The copper plating 910 is formed in the area or location of the future cavity. Next, the copper plated carrier 900 is laminated with a prepreg layer 920 and another seed layer 930. Prepreg 920 can be a impregnated resin layer with embedded glass fabric or similar type of layer. Carrier 900, prepreg 920 and seed layer 930 are laminated together to form one composite structure as shown. Although top and bottom layers are shown in FIG. 9A for the composite structure, the composite structure can be formed on one side only if so desired.

The carrier 900 is then separated from the composite structure forming separate substrates 940 and 945. We will describe further processing of the substrate with respect to only one substrate, but it should be understood that the further process can be applied to both substrates. After separating the carrier 900 from substrate 940, vias 941 are formed in substrate 940 and substrate 940 is coated with a combination litho/cu plating layer 950. The plating layer 950 can be composed of lithographic resin and copper plating. The plating layer 950 is then stripped to expose various portions of substrate 940. The portions exposed can be arranged as needed to achieve a desired pattern.

The process is continued as shown in FIG. 9B according to an exemplary embodiment. In FIG. 9B, substrate 940 with exposed copper layer is further etched to remove seed layer 960 but keep copper portions 970 and copper plating 910. Next, a three stage process is applied to substrate 940. In the three stage process: a SR coating is applied, exposed, and then developed. Following this three stage process, a mask layer 980 is formed on substrate 940 except in the location of the future cavity or copper plating 910. Another etching process is applied to substrate 940 to form a cavity 990. In this etching process, the masked portions of substrate 940 are protected from etching and only the exposed copper plating 910 is etched away. After forming cavity 990, the masking layer 980 is stripped away from substrate 940.

It should be understood that although the description above mentions copper, substitute materials can be used in place of copper. The substitute materials can include a mechanical structure that resists etching or a structure that can be coated to resist etching.

Embodiments of the methods described herein can be used in a number of applications and integrated circuits. For example, the described embodiments could be used in package on package (PoP) semiconductor packages to reduce top ball pad pitch because of the cavity formation in the interposer. Further applications should be readily apparent to those of ordinary skill in the art.

Nothing stated or illustrated depicted in this application is intended to dedicate any component, step, feature, object, benefit, advantage, or equivalent to the public, regardless of whether the component, step, feature, object, benefit, advantage, or the equivalent is recited in the claims.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

The various illustrative logical blocks, modules, and circuits described in connection with the aspects disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

Although some aspects have been described in connection with a device, it goes without saying that these aspects also constitute a description of the corresponding method, and so a block or a component of a device should also be understood as a corresponding method step or as a feature of a method step. Analogously thereto, aspects described in connection with or as a method step also constitute a description of a corresponding block or detail or feature of a corresponding device. Some or all of the method steps can be performed by a hardware apparatus (or using a hardware apparatus), such as, for example, a microprocessor, a programmable computer or an electronic circuit. In some exemplary embodiments, some or a plurality of the most important method steps can be performed by such an apparatus.

The exemplary embodiments described above merely constitute an illustration of the principles of the present disclosure. It goes without saying that modifications and variations of the arrangements and details described herein will become apparent to other persons skilled in the art. Therefore, it is intended that the disclosure be restricted only by the scope of protection of the appended patent claims, rather than by the specific details presented on the basis of the description and the explanation of the exemplary embodiments herein.

In the detailed description above it can be seen that different features are grouped together in exemplary embodiments. This manner of disclosure should not be understood as an intention that the claimed exemplary embodiments require more features than are explicitly mentioned in the respective claim. Rather, the situation is such that inventive content may reside in fewer than all features of an individual exemplary embodiment disclosed. Therefore, the following claims should hereby be deemed to be incorporated in the description, wherein each claim by itself can stand as a separate exemplary embodiment. Although each claim by itself can stand as a separate exemplary embodiment, it should be noted that-although a dependent claim can refer in the claims to a specific combination with one or a plurality of claims-other exemplary embodiments can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods disclosed in the description or in the claims can be implemented by a device comprising means for performing the respective steps or actions of this method.

Furthermore, in some exemplary embodiments, an individual step/action can be subdivided into a plurality of sub-steps or contain a plurality of sub-steps. Such sub-steps can be contained in the disclosure of the individual step and be part of the disclosure of the individual step.

Accordingly, an embodiment of the disclosure can include a computer readable media embodying a method for location estimation. Accordingly, the disclosure is not limited to illustrated examples and any means for performing the functionality described herein are included in embodiments of the disclosure.

While the foregoing disclosure shows illustrative embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order. Furthermore, although elements of the invention may be described or claimed in the singular, the plural is contemplated unless limitation to the singular is explicitly stated.

What is claimed is:

1. A method for producing a cavity within a semiconductor substrate, the method comprising:
forming a plating portion on a cavity location of a carrier;
laminating the carrier with a composite layer;
separating the carrier from the composite layer;
forming a substrate with the separated composite layer and the plating portion; and
forming a cavity in the substrate by etching an exposed plating portion wherein the cavity extends partially through the substrate.

2. The method of claim 1, further comprising forming a seed layer on the carrier.

3. The method of claim 1, further comprising masking the substrate while exposing the plating portion.

4. The method of claim 3, further comprising etching the substrate to remove an unmasked portion.

5. The method of claim 1, wherein the plating portion is copper.

6. The method of claim 1, wherein the composite layer is a pre-impregnated resin layer and a seed layer.

7. The method of claim 6, wherein the pre-impregnated resin layer includes a glass fabric.

8. The method of claim 7, wherein the glass fabric is continuous throughout the pre-impregnated resin layer and offset from a center of the pre-impregnated resin layer.

9. A substrate prepared by a process comprising the steps of:
forming a plating portion on a cavity location of a carrier;
laminating the carrier with a composite layer;
separating the carrier from the composite layer;
forming a substrate with the separated composite layer and the plating portion; and
forming a cavity in the substrate by etching a exposed plating portion wherein the cavity extends partially through the substrate.

10. The process of claim 9, further comprising forming a seed layer on the carrier.

11. The process of claim 9, further comprising masking the substrate while exposing the plating portion.

12. The process of claim 11, further comprising etching the substrate to remove an unmasked portion.

13. The process of claim 9, wherein the plating portion is copper.

14. The process of claim 9, wherein the composite layer is a pre-impregnated resin layer and a seed layer.

15. The process of claim 14, wherein the pre-impregnated resin layer includes a glass fabric.

16. The process of claim 15, wherein the glass fabric is continuous throughout the pre-impregnated resin layer and offset from a center of the pre-impregnated resin layer.

17. A structure comprising:
a substrate defining a cavity in a first side thereof;
a dielectric layer laminated over the substrate; and
a glass fabric embedded in the dielectric layer, wherein the glass fabric is offset from a center of the dielectric layer.

18. The structure of claim 17, wherein the glass fabric is continuous throughout the dielectric layer.

19. The structure of claim 17, wherein the dielectric layer is a pre-impregnated layer.

20. The structure of claim 17, wherein the cavity partially extends through the substrate to a point near a beginning of the glass fabric.
